(19) United States
(12) Patent Application Publication
(10) Pub. No.: US 2025/0098484 A1
(43) Pub. Date: Mar. 20, 2025

(54) DISPLAY PANEL AND TERMINAL DEVICE

(71) Applicants: BOE TECHNOLOGY GROUP CO., LTD., Beijing (CN); CHENGDU BOE OPTOELECTRONICS TECHNOLOGY CO., LTD., Sichuan (CN)

(72) Inventors: Changchang LIU, Beijing (CN); Wei WANG, Beijing (CN); Zhu WANG, Beijing (CN); Xuewei TIAN, Beijing (CN); Yipeng CHEN, Beijing (CN); Yuanzheng GUO, Beijing (CN)

(21) Appl. No.: 18/559,523

(22) PCT Filed: Nov. 16, 2022
(86) PCT No.: PCT/CN2022/132365

§ 371 Date: Nov. 7, 2023

(51) Int. Cl. H10K 59/80; H10K 59/131

(52) U.S. Cl. CPC H10K 59/873; H10K 59/131

(57) ABSTRACT

The present disclosure relates to a display panel. The display panel has a light-transmitting hole, a display area, a peripheral area and a transition area between the light-transmitting hole and the display area. The display panel includes a driving backplane, a barrier dam, a first separation component, a light-emitting device, a photoelectric sensing device and an encapsulation layer. The barrier dam is disposed on the driving backplane and at least surrounds a partial area of the light-transmitting hole. The first separation component is disposed on the driving backplane, the first separation component and the barrier dam are distributed at intervals in a radial direction of the light-transmitting hole, the first separation component includes a first separation pillar at least surrounding the partial area of the light-transmitting hole, and a sidewall of the first separation pillar is provided with a cut-off groove.

### CROSS-REFERENCE

The present application is the 371 application of PCT Application No. PCT/CN2022/132365, filed on Nov. 16, 2022, the entire contents of which are hereby incorporated by reference.

### TECHNICAL FIELD

The present disclosure relates to the field of display technologies, and more particularly, to a display panel and a terminal device.

### BACKGROUND

Display panels have become an indispensable part of terminal devices such as mobile phones, tablets, and televisions. Display panels using organic light-emitting diodes are widely used. In order to realize functions such as under-screen photography or detection, display panels with openings are often used, so as to, by providing the openings, avoid shielding cameras or other photosensitive elements.

It should be noted that the information disclosed in the Background section above is only for enhancing the understanding of the background of the present disclosure, and thus may include information that does not constitute prior art known to those of ordinary skill in the art.

### SUMMARY

The present disclosure provides a display panel and a terminal device.

According to an aspect of the present disclosure, there is provided a display panel with a light-transmitting hole, a display area located outside the light-transmitting hole, a peripheral area located outside the display area and a transition area located between the light-transmitting hole and the display area, including:
a driving backplane;
at least one barrier dam, disposed on the driving backplane, located in the transition area, and at least surrounding a partial area of the light-transmitting hole;
a first separation component, disposed on the driving backplane and located in the transition area, wherein the first separation component and the barrier dam are distributed at intervals in a radial direction of the light-transmitting hole, the first separation component includes a first separation pillar at least surrounding the partial area of the light-transmitting hole, and a sidewall of the first separation pillar is provided with a cut-off groove at least surrounding the partial area of the light-transmitting hole;
a plurality of light-emitting devices, disposed on a side of the driving backplane and located in the display area;
at least one photoelectric sensing device, disposed between the barrier dam and the first separation component; and
an encapsulation layer, covering the light-emitting device, the barrier dam and the first separation component, wherein the encapsulation layer includes an organic layer defined on a side of the barrier dam away from the light-transmitting hole.

According to an aspect of the present disclosure, there is provided a terminal device, including:
the display panel described in any of the above embodiments; and
a photosensitive element, disposed on a side of the driving backplane away from the light-emitting device and overlapped with the light-transmitting hole.

It should be noted that the above general description and the following detailed description are merely exemplary and explanatory and should not be construed as limiting of the disclosure.

### BRIEF DESCRIPTION OF THE DRAWINGS

The accompanying drawings, which are incorporated in and constitute a part of this specification, illustrate embodiments consistent with the present disclosure and together with the description serve to explain the principles of the present disclosure. Apparently, the drawings in the following description are only some embodiments of the present disclosure, and those skilled in the art can obtain other drawings according to these drawings without creative efforts.

FIG. 1 is a top view of a display panel according to an embodiment of the present disclosure.

FIG. 2 is a partial top view of a display panel according to an embodiment of the present disclosure.

FIG. 3 is a cross-sectional view taken along line A-A in FIG. 1.

FIG. 4 is a cross-sectional view taken along line B-B in FIG. 1.

FIG. 5 is a schematic diagram of a barrier dam and a separation pillar in the embodiment in FIG. 2.

FIG. 6 is a schematic diagram of a pixel circuit of a display panel according to an embodiment of the present disclosure.

FIG. 7 is a top view of a plurality of photoelectric sensing devices of a display panel according to an embodiment of the present disclosure.

FIG. 8 is a top view of a plurality of sensing electrodes of a display panel according to an embodiment of the present disclosure.

FIG. 9 is a top view of a sensing electrode of a display panel according to another embodiment of the present disclosure.

FIG. 10 is a top view of a photoelectric sensing layer of a display panel according to an embodiment of the present disclosure.

FIG. 11 is a top view of a sensing filter part and a lead layer of a display panel according to an embodiment of the present disclosure.

FIG. 12 is a top view of a lead layer of a display panel according to an embodiment of the present disclosure.

FIG. 13 is a top view of a lead layer of a display panel according to another embodiment of the present disclosure.

FIG. 14 is a top view of a sensing filter part of a display panel according to an embodiment of the present disclosure.

FIG. 15 is a top view of a lead, a data line and a power line of a display panel according to an embodiment of the present disclosure.

FIG. 16 is a top view of a light-shielding layer of a display panel according to an embodiment of the present disclosure.

FIG. 17 is a top view of a sensing filter part of a display panel according to another embodiment of the present disclosure.

FIG. 18 is a schematic diagram of a terminal device according to an embodiment of the present disclosure.

### DETAILED DESCRIPTION

Example embodiments will now be described more fully with reference to the accompanying drawings. However, exemplary embodiments may be implemented in many forms and should not be construed as limited to the embodiments set forth herein. Instead, these embodiments are provided so that the present disclosure will be thorough and complete, and will fully convey the concept of the exemplary embodiments to those skilled in the art. The same reference numerals in the drawings denote the same or similar structures, and thus their detailed descriptions will be omitted. In addition, the drawings are only schematic representations of the present disclosure and, thus, are not necessarily drawn to scale.

The terms “a”, “an”, “the”, “said” and “at least one” are used to indicate the presence of one or more elements/components and the like; the terms “including/comprising” and “have” are used to indicate a nonexclusive meaning and refer to that there may be additional elements/components and the like in addition to the listed elements/components and the like. The terms “first”, “second”, “third” and the like are only used as a marker, not a limit on the number of objects related thereto.

A row direction X and a column direction Y herein are only two directions that cross each other. For example, the row direction X and the column direction Y may be perpendicular to each other. In the drawings of the present disclosure, the row direction X may be horizontal, and the column direction Y may be vertical, but are not limited thereto. If the display panel is rotated, actual orientations of the row direction X and the column direction Y may change.

Feature A being “overlapped with” feature B means that an orthographic projection of feature A on a substrate and an orthographic projection of feature B on the substrate at least partially overlap. Alternatively, the orthographic projection may also be an orthographic projection on any plane parallel to an extension direction of a driving backplane.

Feature A being in the “same layer” as feature B herein means that feature A and feature B may be formed at the same time, they are discontinuous or continuous different areas in the same film layer, and they are not separated by other film layers in a direction perpendicular to a substrate.

As described above, display panels have become an indispensable part of terminal devices such as mobile phones, tablets, and televisions. Display panels using organic light-emitting diodes are widely used. In order to realize functions such as under-screen photography or detection, display panels with openings are often used, so as to, by providing the openings, avoid shielding cameras or other photosensitive elements. However, due to different lighting conditions in different application environments, effects of the display panels in realizing functions such as displaying images or image collection still need to be improved.

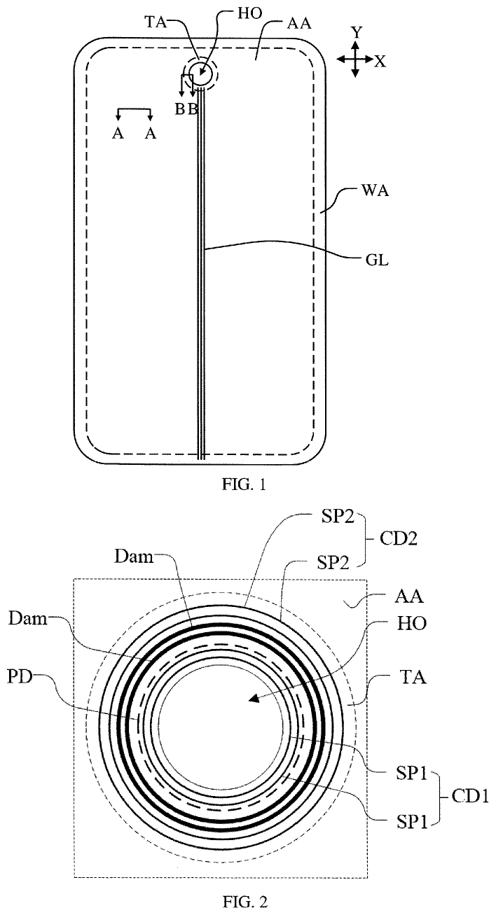

Embodiments of the present disclosure provide a display panel. As shown in FIG. 1, the display panel has a light-transmitting hole HO, a display area AA and a peripheral area WA. The display area AA is located outside the light-transmitting hole HO, and the peripheral area WA is located outside the display area AA. Moreover, there may be a transition area TA between the light-transmitting hole HO and the display area AA.

As shown in FIGS. 2 to 5, the display panel may include a driving backplane BP, a barrier dam Dam, a first separation component CD1, a light-emitting device LD, a photoelectric sensing device PD and an encapsulation layer TFE.

In some embodiments, the barrier dam Dam is disposed on the driving backplane BP and is located in the transition area TA. The barrier dam Dam at least surrounds a partial area of the light-transmitting hole HO.

The first separation component CD1 is disposed on the driving backplane BP and is located in the transition area TA, and is spaced apart from the barrier dam Dam along a radial direction of the light-transmitting hole HO. The first separation component CD includes a first separation pillar SP1 at least surrounding the partial area of the light-transmitting hole HO. A sidewall of the first separation pillar SP1 is provided with a cut-off groove SLG at least surrounding the partial area of the light-transmitting hole HO.

A plurality of light-emitting devices LD are disposed on a side of the driving backplane BP and located in the display area AA.

The photoelectric sensing device PD is disposed between the barrier dam Dam and the first separation component CD1.

The encapsulation layer TFE covers the light-emitting device LD, the barrier dam Dam and the first separation component CD1, and the encapsulation layer TFE includes an organic layer IJP defined on a side of the barrier dam Dam away from the light-transmitting hole HO.

According to the display panel in embodiments of the present disclosure, external light transmitting the light-transmitting hole HO can be received by the photosensitive element, thereby collecting images. Moreover, a position of the organic layer IJP in the encapsulation layer TFE can be defined by the barrier dam Dam to prevent the organic layer IJP from entering the light-transmitting hole HO. Furthermore, a light-emitting material forming the light-emitting device LD can be cut off through the cut-off groove SLG of the first separation component CD1, preventing water vapor from entering an interior of the display area AA via the light-transmitting hole HO to cause erosion of the light-emitting device LD, that is, a path of water vapor intrusion is cut off through the cut-off groove SLG.

The ambient light may be detected by the photoelectric sensing device PD, so that a display effect can be adjusted according to the ambient light. For example, the brightness of the light-emitting device LD is adjusted to improve the display effect. Alternatively, the photosensitive element can also be adjusted according to the ambient light to improve an imaging effect. Furthermore, the photoelectric sensing device PD is located between the barrier dam Dam and the first separation component CD1, realizing the integration of the display panel and the photoelectric sensing device PD without occupying the display area AA, so as to minimize the occupation space while achieving the ambient light detection.

A structure of the display panel of the present disclosure is described in detail below.

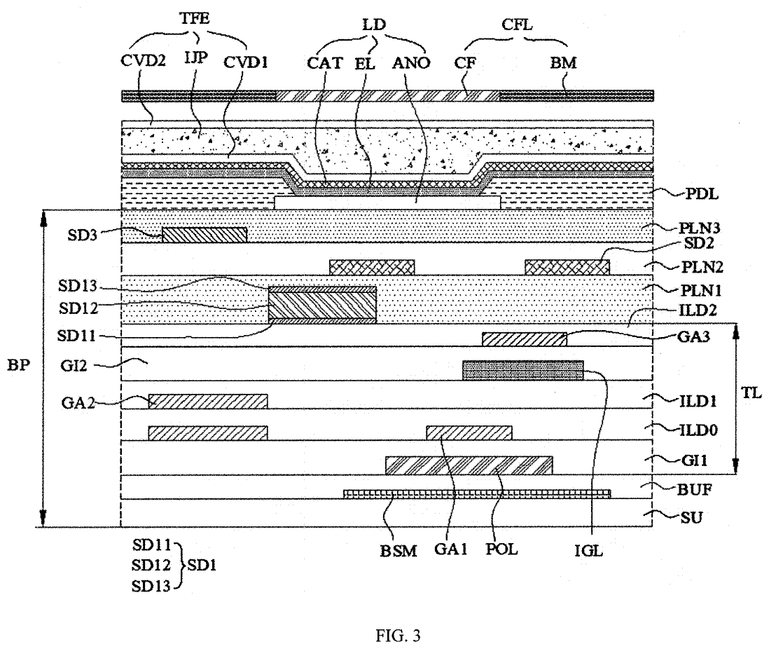

As shown in FIGS. 3 to 5, the display panel may be provided with the light-transmitting hole HO, and a side of the driving backplane BP away from the light-emitting device LD may be provided with the photosensitive element. The photosensitive element is arranged opposite to the light-transmitting hole HO and can receive light reaching a backlight side of the display panel (the side of the driving backplane BP away from the light-emitting device LD) from a light-emitting side of the display panel (a side of the encapsulation layer TFE away from the driving backplane BP) via the light-transmitting hole HO, so that an image is formed. The photosensitive element may be a camera for capturing the image or a sensor for fingerprint recognition. A shape of the light-transmitting hole HO may be circular, polygonal or other shapes, which is not particularly limited here. Moreover, the number of light-transmitting holes HO may be one, two or more. One light-transmitting hole HO is only taken as an example for illustration herein, and if a plurality of light-transmitting holes HO are used, reference may be made to the embodiment of the one light-transmitting hole HO.

As shown in FIGS. 1 and 2, the display panel may further include the display area AA and the peripheral area WA located outside the display area AA, and the display area AA and the peripheral area WA may be located outside the light-transmitting hole HO for displaying the image. A partial boundary of the light-transmitting hole HO may be coincided with a boundary of the display area AA. Alternatively, the boundary of the light-transmitting hole HO may also be at a certain distance from the boundary of the display area AA. The peripheral area WA may be a continuous or discontinuous annular area surrounding the display area AA, that is, the peripheral area WA is disposed to at least partially surround the display area AA, and a shape of the peripheral area WA is not specifically limited here.

Furthermore, the display panel may further include the transition area TA between the light-transmitting hole HO and the display area AA. The transition area TA may surround outside the light-transmitting hole HO and separate the display area AA and the light-transmitting hole HO. Both the transition area TA and the light-transmitting hole HO do not emit light, that is, no light-emitting device LD is disposed between the light-transmitting hole HO and the transition area TA.

As shown in FIGS. 1 and 15, the driving backplane BP has a driving circuit for driving the light-emitting device LD to emit light. The driving circuit may include a pixel circuit located in the display area AA and a peripheral circuit located in the peripheral area WA.

In some embodiments, there are a plurality of pixel circuits distributed into a plurality of rows and columns along a row direction X and a column direction Y. One pixel circuit may be coupled to one light-emitting device LD. Alternatively, there may also be a case that one pixel circuit is coupled to a plurality of light-emitting devices LD. The pixel circuit being coupled with the light-emitting device LD in a one-to-one correspondence is only taken as an example for illustration herein. The light-transmitting hole HO may penetrate at least part of film layers of the driving backplane BP.

The pixel circuit may include a plurality of transistors and capacitors, which may be a pixel circuit such as 3T1C, 7T1C, and 8T1C. nTmC indicates that the pixel circuit includes n transistors (indicated by the letter “T”) and m capacitors (indicated by the letter “C”).

The peripheral circuit may be coupled to the pixel circuit and the light-emitting device LD, and may control a current passing through the light-emitting device LD through the pixel circuit, thereby controlling the brightness of the light-emitting device LD. The peripheral circuit may include a gate driving circuit, a light-emitting control circuit, etc. Alternatively, the peripheral circuit may further include other circuits. A specific structure of the peripheral circuit is not particularly limited here.

A pixel circuit with a 7T1C structure is taken as an example for illustration in the following.

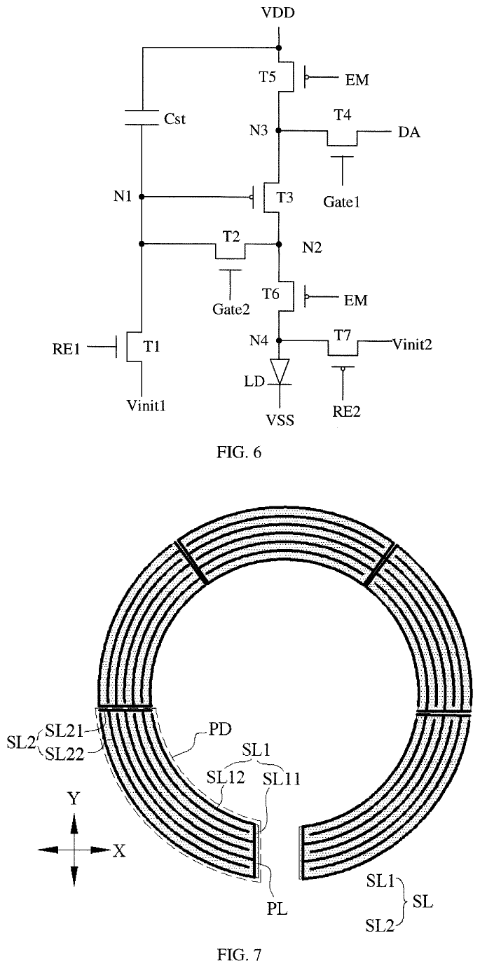

As shown in FIG. 6, the pixel circuit may include a first reset transistor T1, a compensation transistor T2, a driving transistor T3, a writing transistor T4, a first control transistor T5, a second control transistor T6, a second reset transistor T7 and a storage capacitor Cst. Each transistor includes a gate, a first electrode and a second electrode, and a control signal is applied to the gate to make the first electrode and the second electrode turn on or off. The storage capacitor Cst may include a first plate and a second plate overlapped with each other.

As shown in FIG. 6, a gate of the first control transistor T5 is used to input a light-emitting control signal EM, a first electrode of the first control transistor T5 is used to input a first power signal VDD, and a second electrode of the first control transistor T5 is coupled to a first electrode of the driving transistor T3.

A gate of the driving transistor T3 is coupled to a first node N1, a second electrode of the driving transistor T3 and a first electrode of the second control transistor T6 are coupled to a second node N2. A second electrode of the second control transistor T6 and a terminal of a light-emitting device LD are coupled to a fourth node N4. A gate of the second control transistor T6 is used to input the light-emitting control signal EM. The other terminal of the light-emitting device LD is used to receive a second power signal VSS.

A gate of the first reset transistor T1 is used to input a first reset control signal RE1, a first electrode of the first reset transistor T1 is used to input a first reset signal ViniT1, and a second electrode of the first reset transistor T1 is coupled to the first node N1, that is, coupled to the gate of the driving transistor T3.

A gate of the writing transistor T4 is used to input a first scan signal Gate1, a first electrode of the writing transistor T4 is used to input a data signal DA, and a second electrode of the writing transistor T4 and a second electrode of the first control transistor T5 are coupled to a third node N3.

A gate of the compensation transistor T2 is used to input a second scan signal Gate2, a first electrode of the compensation transistor T2 and the second electrode of the driving transistor T3 are coupled to the second node N2, and a second electrode of the compensation transistor T2 is coupled to the first node N1, that is, the second electrode is coupled to the gate of the driving transistor T3.

A gate of the second reset transistor T7 is used to input a second reset control signal RE2, a first electrode of the second reset transistor T7 is used to input a second reset signal ViniT2, and a second electrode of the second reset transistor T7 is coupled to the fourth node N4, that is, coupled to the second electrode of the second control transistor T6 and the light-emitting device LD.

The first plate of the storage capacitor Cst is coupled to the first node N1, that is, coupled to the gate of the driving transistor T3, and the second plate of the storage capacitor Cst is used to input the first power signal VDD.

The following explains a working principle of the above pixel circuit.

In a reset phase, the first reset transistor T1 may be turned on through the first reset control signal RE1, and the first reset signal Vinit1 is written to the first node N1. At the same time, the second reset transistor T7 may be turned on through the second reset control signal RE2, and the second reset signal ViniT2 is written to the fourth node N4. Thereby, the gate of the driving transistor T3 and the light-emitting device LD may be reset.

In a writing phase, the writing transistor T4 and the compensation transistor T2 are turned on through the first scan signal Gate1 and the second scan signal Gate2, and the data signal DA is written to the first node N1 through the third node N3 and the second node N2, until the potential reaches Vdata+Vth, where Vdata is a voltage of the data signal DA, and Vth is a threshold voltage of the driving transistor T3. The first scan signal Gate1 and the second scan signal Gate2 may be the same signal, or may be two synchronized signals. In addition, the first scan signal Gate1 and the second scan signal Gate2 may be high-frequency signals, which is beneficial to reducing a load of a source signal of the driving transistor T3.

In a light-emitting phase, the first control transistor T5 and the second control transistor T6 are turned on by the light-emitting control signal EM. The driving transistor T3 is turned on under the action of a voltage Vdata+Vth stored in the storage capacitor Cst and the first power signal VDD. The light-emitting device LD emits light under the action of the first power signal VDD and the second power signal VSS. During this process, the first electrode of the driving transistor T3 serves as the source, and the second electrode of the driving transistor T3 serves as the drain.

An output current of the driving transistor T3 satisfies the following formula:

$$I = ( μ WCox / 2 L ) {( Vgs - Vth )}^{2}$$

where I is the output current of the driving transistor T3; μ is a carrier mobility; Cox is a gate capacitance per unit area, W is a channel width of the driving transistor T3, L is a channel length of the driving transistor T3, Vgs is a gate-source voltage difference (a voltage difference between the gate and the source) of the driving transistor T3, and Vth is a threshold voltage of the driving transistor T3.

According to the above formula for the output current of the driving transistor T3, by letting the gate voltage of the driving transistor T3 in the pixel circuit of the present disclosure as Vdata+Vth and the source voltage of the driving transistor T3 as VDD in the above formula, it may be obtained that the output current of the driving transistor T3 is I=(μ WCox/2L) (Vdata+Vth−VDD−Vth)². It can be seen that the output current of the pixel circuit has nothing to do with the threshold voltage Vth of the driving transistor T3, but is only related to Vdata, thereby eliminating the impact of the threshold voltage of the driving transistor T3 on its output current, and the control of the output current can be realized only through the voltage Vdata of the data signal DA, so as to control the brightness of the light-emitting device LD.

Each transistor in the pixel circuit may be a polycrystalline silicon transistor (that is, a channel of the transistor is polycrystalline silicon), such as a P-type low-temperature polycrystalline silicon transistor or an N-type low-temperature polycrystalline silicon transistor. Alternatively, a metal oxide transistor may also be used, that is, the channel of the transistor is a metal oxide such as indium gallium zinc oxide. When a high level is input to a gate of the P-type low-temperature polycrystalline silicon transistor, the P-type low-temperature polycrystalline silicon transistor may be turned off, and when a low-level signal is input to the gate of the P-type low-temperature polycrystalline silicon transistor, the P-type low-temperature polycrystalline silicon transistor may be turned on. When a low level is input to a gate of the N-type low-temperature polycrystalline silicon transistor, the N-type low-temperature polycrystalline silicon transistor may be turned off, and when a high-level signal is input to the gate of the N-type low-temperature polycrystalline silicon transistor, the N-type low-temperature polycrystalline silicon transistor may be turned on. The metal oxide transistor may be the N-type metal oxide transistor, which may be turned on when the high level is input to the gate, and turned off when the low level is input to the gate.

In some embodiments of the present disclosure, the 7T1C pixel circuit may adopt LTPO (LTPS+Oxide) technologies. Specifically, the driving transistor T3, the writing transistor T4, the second reset transistor T7, the first control transistor T5 and the second control transistor T6 may be P-type low-temperature polycrystalline silicon transistors. The first reset transistor T1 and the compensation transistor T2 may be N-type metal oxide transistors. Since the P-type low-temperature polycrystalline silicon transistor has a high carrier mobility, thereby facilitating the realization of a display panel with high resolution, high response speed, high pixel density, and high opening rate, in order to obtain a higher carrier mobility and improve the response speed. Furthermore, the leakage can be reduced through the N-type metal oxide transistor.

Alternatively, in other embodiments of the present disclosure, the 7T1C pixel circuit may also adopt the LTPS technologies, that is, each transistor is a low-temperature polycrystalline silicon transistor.

In addition, as shown in FIGS. 6 and 15, in order to transmit a signal, the driving backplane BP may include a plurality of scan lines, data lines DAL and power lines VDL, where the scan lines may extend along the row direction X and may be distributed along the column direction Y, and the data lines DAL and the power lines VDL may extend along the column direction Y and may be distributed along the row direction X.

The plurality of scan lines may be used to transmit the first scan signal Gate1, the second scan signal Gate2, the first reset control signal RE1, the second reset control signal RE2 and the light-emitting control signal EM mentioned above. Gates of some transistors in the same row of pixel circuits PC may be coupled to one scan line, so that these transistors can be turned on or off at the same time.

The data line DAL is used to transmit the above-mentioned data signal DA. First electrodes of writing transistors T4 of the same column of pixel circuits PC may be coupled to the same data line DAL to input the data signal DA to one column of pixel circuits PC.

The power line VDL is used to transmit the first power signal VDD. First electrodes of first control transistors T5 of the same column of pixel circuits PC are coupled to the second plate of the storage capacitor Cst, so as to input the first power signal VDD to one column of pixel circuits PC.

The data lines DAL may be divided into a plurality of data line groups DG, and each data line group DG includes two adjacent data lines DAL. The power lines VDL may be divided into a plurality of power line groups VG, and each power line group VG includes two adjacent power lines VDL. The data line groups DG and the power line groups VG may be alternately distributed at intervals along the row direction X, and one data line group DG is disposed between two adjacent power line groups VG.

The same column of pixel circuits PC is coupled to one data line DAL and one power line VDL.

Based on the 7T1C pixel circuit using the LTPO technologies, the following is a detailed description of each film layer of the driving backplane BP.

As shown in FIGS. 3-5, the driving backplane BP may include a substrate SU and a transistor layer TL.

In some embodiments, the substrate SU may a base substrate of the driving backplane BP, which can carry the pixel circuit and the peripheral circuit. The substrate SU may be a hard or flexible structure, and may be a single-layer or multi-layer structure, which is not specifically limited here.

The transistor layer TL is disposed on a side of the substrate SU and includes each transistor and storage capacitor of the pixel circuit. Alternatively, the transistor layer TL may further include all transistors and storage capacitors of the driving circuit.

In some embodiments of the present disclosure, the transistor layer TL may include a first semiconductor layer POL, a first gate insulation layer GI1, a first gate layer GA1, a first insulation layer ILD0, a second gate layer GA2, a second insulation layer ILD1, a second semiconductor layer IGL, a second gate insulation layer GI2, a third gate layer GA3 and a third insulation layer ILD2 sequentially stacked in a direction away from the substrate SU.

In some embodiments, the first semiconductor layer POL may be disposed on a side of the substrate SU and includes channels of the driving transistor T3, the writing transistor T4, the second reset transistor T7, the first control transistor T5 and the second control transistor T6, and a material of the first semiconductor layer POL may be polycrystalline silicon.

The first gate insulation layer GI1 may cover the first semiconductor layer POL, and a material of the first gate insulation layer GI1 may be an insulation material such as silicon nitride or silicon oxide.

The first gate layer GA1 may be disposed on a surface of the first gate insulation layer GI1 away from the substrate SU, and includes the gate of each transistor and the first plate of the storage capacitor. The first plate of the storage capacitor may be reused as the gate of the driving transistor T3.

The first insulation layer ILD0 may cover the first gate layer GA1, and a material of the first insulation layer ILD0 may be the insulation material such as silicon nitride or silicon oxide.

The second gate layer GA2 may be disposed on a surface of the first insulation layer ILD0 away from the substrate SU, and includes the second plate of the storage capacitor. The second plate is overlapped with the first plate to form the storage capacitor.

The second insulation layer ILD1 may cover the second gate layer GA2, and a material of the second insulation layer ILD1 may include an inorganic insulation material such as silicon nitride, silicon oxide, silicon oxynitride, etc., which is not specifically limited here. The second insulation layer ILD1 may be a single-layer or multi-layer structure.

The second semiconductor layer IGL may be disposed on a side of the second insulation layer ILD1 away from the substrate SU, and a material of the second semiconductor layer IGL may be a metal oxide such as indium gallium zinc oxide. The second semiconductor layer IGL may include channels of the first reset transistor T1 and the compensation transistor T2.

The second gate insulation layer GI2 may cover the second semiconductor layer IGL, and a material of the second gate insulation layer GI2 may be the insulation material such as silicon nitride or silicon oxide.

The third gate layer GA3 may be disposed on a surface of the second gate insulation layer GI2 away from the substrate SU, and includes a second reset control line REL2 and a second scan line GAL2. The third gate layer GA3 is overlapped with at least a partial area of the second semiconductor layer IGL.

The third insulation layer ILD2 may cover the third gate layer GA3. The third insulation layer ILD2 may be a single-layer or multi-layer structure, and a material of the third insulation layer ILD2 may include the inorganic insulation material such as silicon nitride or silicon oxide, or an organic insulation material such as insulation resin.

Furthermore, the driving backplane may further include a first source-drain layer SD1, a first planarization layer PLN1, a second source-drain layer SD2, a second planarization layer PLN2, a third source-drain layer SD3 and a third planarization layer PLN3 disposed on a side of the transistor layer TL in the direction away from the substrate SU.

In some embodiments, the first source-drain layer SD1 may be disposed on a surface of the third insulation layer ILD2 away from the substrate SU. The first source-drain layer SD1 may be a single-layer or multi-layer structure, and a material of the first source-drain layer SD1 may include one or more of metals such as Ti, Al, Mg, Ag, etc. For example, the first source-drain layer SD1 may include a first sub-layer SD11, a second sub-layer SD12 and a third sub-layer SD13 sequentially stacked in the direction away from the substrate SU. The first sub-layer SD11 and the third sub-layer SD13 may use the same metal material, for example, Ti, and the second sub-layer SD12 may use a different metal material, such as Al, from the material of the first sub-layer SD11 and the third sub-layer SD13.

The first planarization layer PLN1 may cover the first source-drain layer SD1, and a material of the first planarization layer PLN1 may the insulation material such as resin. In addition, a passivation layer may be included, which may cover the first source-drain layer SD1, and the first planarization layer PLN1 may cover the passivation layer.

The second source-drain layer SD2 may be disposed on a surface of the first planarization layer PLN1 away from the substrate SU. The second source-drain layer SD2 may be a single-layer or multi-layer structure, and its material may include one or more of metals such as Ti, Al, Mg, Ag, etc. For example, the second source-drain layer SD2 may have the same three-layer structure as the first source-drain layer SD1.

The second planarization layer PLN2 may cover the second source-drain layer SD2, and its material may be the insulation material such as resin.

The third source-drain layer SD3 may be disposed on a surface of the second planarization layer PLN2 away from the substrate SU. The third source-drain layer SD3 may be a single-layer or multi-layer structure, and its material may include one or more of metals such as Ti, Al, Mg, Ag, etc. For example, the third source-drain layer SD3 may have the same three-layer structure as the first source-drain layer SD1. The third source-drain layer SD3 may include the data line DAL and the power line VDL.

The third planarization layer PLN3 may cover the third source-drain layer SD3, and its material may be the insulation material such as resin.

In addition, as shown in FIGS. 3 to 5, the driving backplane may further include a light-shielding layer BSM and a buffer layer BUF. The light-shielding layer BSM may be disposed on the side of the substrate SU, the transistor layer TL is located on a side of the light-shielding layer BSM away from the substrate SU. The buffer layer BUF covers the light-shielding layer BSM, and the first semiconductor layer POL is disposed on a surface of the buffer layer BUF away from the substrate SU. A material of the buffer layer BUF may include the insulation material such as silicon nitride or silicon oxide, and the buffer layer BUF may be a single-layer or multi-layer structure.

A material of the light-shielding layer SBM is a reflective or light-absorbing material, and the light-shielding layer SBM is at least overlapped with a channel of a transistor to prevent light from affecting the driving transistor T3. For example, the light-shielding layer SBM is overlapped with the channel of the driving transistor T3.

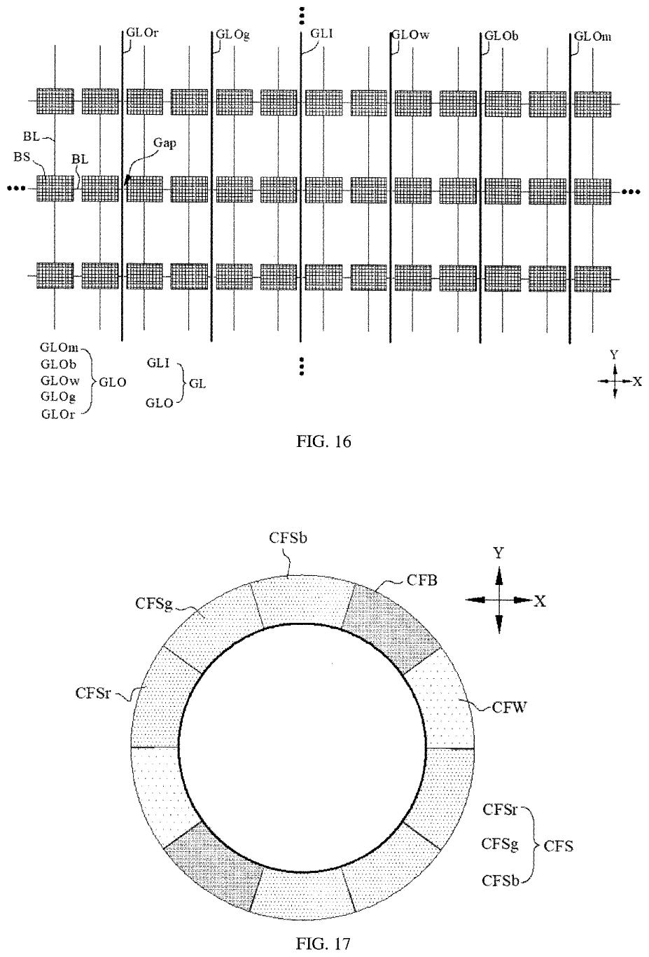

In some embodiments of the present disclosure, as shown in FIG. 16, the light-shielding layer BSM may include a plurality of light-shielding units BS distributed in an array and light-shielding lines BL connecting respective light-shielding units BS along the row direction X and the column direction Y, thereby forming the light-shielding layer BSM with a mesh structure. One light-shielding unit BS is overlapped with at least one transistor of at least one pixel circuit. For example, the light-shielding units BS may be in a one-to-one correspondence with the pixel circuits, and one light-shielding layer SBM is overlapped with a channel of a driving transistor T3 of one pixel circuit. Furthermore, in order to reduce the resistance, at least one of the light-shielding line BL and the light-shielding unit BS may be coupled to the power line VDL, so that the light-shielding layer BSM and the power line VDL are regarded as an overall network.

In some embodiments of the present disclosure, as shown in FIGS. 3 to 5, there are at least the first gate insulation layer GI1, the first insulation layer ILD0, the second insulation layer ILD1, the second gate insulation layer GI2 and the third insulation layer ILD2 stacked in the transition area TA, and the light-transmitting hole HO may also penetrate these film layers until the substrate SU is exposed, and the first planarization layer PLN1 to the third planarization layer PLN3 may be located outside the transition area TA.

Two adjacent columns of pixel circuits may be arranged symmetrically, that is, two adjacent columns of pixel circuits may be arranged symmetrically about a symmetry axis extending along the column direction Y, and the two columns of pixel circuits are located on both sides of the symmetry axis. The symmetrical arrangement here means that structures and positions of the transistor and the storage capacitor are symmetrical about this symmetry axis. In addition, as shown in FIG. 15, power line groups VG and data line groups DG coupling with two adjacent pixel circuits are also symmetrically arranged.

In some other embodiments of the present disclosure, channels of the transistors of the pixel circuit may be located on the same layer, and their materials may be polycrystalline silicon, and each transistor is a P-type polycrystalline silicon transistor. Furthermore, the above-mentioned third source-drain layer SD3 and third planarization layer PLN3 may not be provided, and the power line VDL and the data line DAL are located in the second source-drain layer SD2.

As shown in FIG. 3, each light-emitting device LD may be disposed on the side of the driving backplane BP. For example, the light-emitting device LD may be disposed on the surface of the second planarization layer PLN2 away from the substrate SU. Each light-emitting device LD is located in the display area AA. Moreover, the light-emitting device LD may include a first electrode ANO, a light-emitting layer EL and a second electrode CAT stacked in the direction away from the driving backplane BP. The light-emitting device LD may be an Organic Light-Emitting Diode (OLED). Alternatively, it may also be a micron Light-Emitting Diode (LED), a mini LED, a QLED or other light-emitting devices.

As shown in FIG. 3, the first electrodes ANO may be disposed on the side of the driving backplane BP and distributed in an array. For example, the first electrode ANO may be disposed on the surface of the second planarization layer PLN2 away from the substrate SU. The light-emitting layer EL may include a hole injection layer, a hole transport layer, a light-emitting material layer, an electron transport layer and an electron injection layer stacked in the direction away from the driving backplane BP. Individual light-emitting devices LD may share the second electrode CAT, that is, the second electrode CAT may be a continuous whole-layer structure, and the second electrode CAT may extend to the transition area TA and the peripheral area WA, and cover the separation pillar SP and the barrier dam Dam. The second electrode CAT may also be disconnected at the cut-off groove SLG. The first electrodes ANO are distributed in an array in the display area AA and are coupled to the pixel circuit, and each light-emitting device LD may emit light independently.

In addition, as shown in FIG. 3, in order to limit a light-emitting range of the light-emitting device LD to prevent crosstalk, a pixel definition layer PDL may be disposed on a surface where the first electrode ANO is disposed. The pixel definition layer PDL is located in the display area AA, and may be provided with an opening exposing each first electrode ANO, and the light-emitting layer EL is stacked with the first electrode ANO in the opening. For example, the pixel definition layer PDL and the first electrode ANO are both disposed on the surface of the second planarization layer PLN2 away from the substrate SU. The opening of the pixel definition layer PDL may be smaller than the first electrode ANO exposed by this opening. Since the light-emitting layer EL has the whole-layer structure, in addition to being stacked with the first electrode ANO in the opening, the light-emitting layer EL also covers the pixel definition layer PDL and extends into the transition area TA.

The light-emitting material layers of different light-emitting devices LD are spaced apart from each other, so that the light-emitting device LD may directly emit monochromatic light, and light-emitting colors of different light-emitting devices LD may be different, thereby achieving the color display. Alternatively, light-emitting layers EL of different light-emitting devices LD may also be spaced apart from each other. In addition, the light-emitting material layers of individual light-emitting devices LD have a continuous whole-layer structure, so that light-emitting colors of the individual light-emitting devices LD are the same. The light-emitting devices LD cooperate with a color filter layer CFL located on a side of the light-emitting devices LD away from the driving backplane BP to achieve the color display.

As shown in FIG. 2, the barrier dam Dam is disposed on the driving backplane BP and is located in the transition area TA. The barrier dam Dam at least surrounds the partial area of the light-transmitting hole HO. For example, the barrier dam Dam is an annular structure surrounding outside the light-transmitting hole HO. The annular structure refers to a closed structure surrounding the light-transmitting hole HO, and a shape of the annular structure may be a circle, an ellipse, or a polygon such as a rectangle. The shape of the annular structure may be the same as the shape of the light-transmitting hole. Alternatively, the barrier dam Dam may also be arc-shaped or other non-closed shapes, and may also be formed by a plurality of discontinuous barrier units distributed at intervals along the annular trajectory. Each light-emitting device LD may be located outside a range surrounded by the barrier dam Dam.

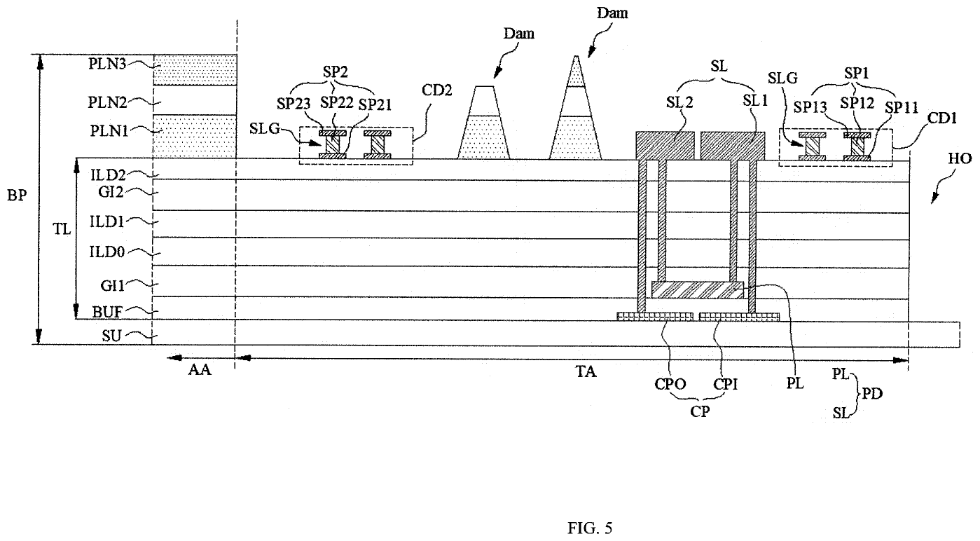

The barrier dam Dam may be a single-layer structure, which may be disposed in the same layer as one or more of the first planarization layer PLN1, the second planarization layer PLN2, the third planarization layer PLN3 and the pixel definition layer PDL, or it may be disposed in the same layer as other insulation film layers. The number of barrier dams Dam may be more than one. As shown in FIG. 5, in some embodiments of the present disclosure, two barrier dams Dam may be disposed outside the light-transmitting hole HO. The two barrier dams Dam concentrically surround outside the light-transmitting hole HO, and a height of a barrier dam Dam away from the light-transmitting hole HO is smaller than a height of a barrier dam Dam close to the light-transmitting hole HO, so that a plurality of restrictions may be placed on the boundary of the organic layer IJP to prevent it from crossing the barrier dam Dam. The barrier dam Dam away from the light-transmitting hole HO may have a single-layer structure, and may be disposed in the same layer as the first planarization layer PLN1. The barrier dam Dam close to the light-transmitting hole HO may have a multi-layer structure, with one layer being disposed in the same layer as the first planarization layer PLN1 and one layer being disposed in the same layer as the second planarization layer PLN2.

As shown in FIGS. 2, 3 and 4, the first separation component CD1 is disposed on the driving backplane BP and is located in the transition area TA. The first separation component CD1 and the barrier dam Dam are distributed at intervals along the radial direction of the light-transmitting hole HO. For example, the first separation component CD1 is disposed between the light-transmitting hole HO and the barrier dam Dam, or the barrier dam Dam may be disposed on a side of the first separation component CD1 away from the light-transmitting hole HO.

As shown in FIG. 5, the first separation component CD1 includes a first separation pillar SP1 at least surrounding the partial area of the light-transmitting hole HO. A sidewall of the first separation pillar SP1 may be provided with a cut-off groove SLG at least surrounding the partial area of the light-transmitting hole HO. The light-emitting layer EL covers the first separation pillar SP1 and is disconnected at the cut-off groove SLG, thereby cutting off, through the first separation pillar SP1, a path for water vapor to erode the light-emitting device LD.

As shown in FIG. 5, in some embodiments of the present disclosure, the first separation pillar SP1 is an annular structure surrounding the light-transmitting hole HO, and the cut-off groove SLG is an annular groove surrounding the light-transmitting hole HO. When the light-emitting layer EL is formed, since it is difficult for a material of the light-emitting layer EL to enter the interior of the cut-off groove SLG, the light-emitting layer EL is disconnected at the cut-off groove SLG.

As shown in FIG. 5, in order to form the cut-off groove SLG of the first separation pillar SP1, the first separation pillar SP1 may include a plurality of separation layers stacked in the direction away from the substrate SU. By etching one separation layer, a side etching on the first separation pillar SP1 is realized to form the cut-off groove SLG. For example, the first separation pillar SP1 may be disposed in the same layer as the first source-drain layer SD1, and the first separation pillar SP1 may include a first separation layer SP11 disposed in the same layer as the first sub-layer SD11, a second separation layer SP12 disposed in the same layer as the second sub-layer SD12 and a third separation layer SP13 disposed in the same layer as the third sub-layer SD13. A boundary of the second separation layer SP12 is retracted inside boundaries of the first separation layer SP11 and the third separation layer SP13, forming the cut-off groove SLG.

In addition, as shown in FIGS. 3 to 5, the display panel may include a second separation component CD2, which may be disposed on the driving backplane BP and located in the transition area TA. The second separation component CD2 and the barrier dam Dam are distributed at intervals along the radial direction of the light-transmitting hole HO. The barrier dam Dam is located between the first separation component CD1 and the second separation component CD2.

As shown in FIG. 5, the second separation component CD2 includes a second separation pillar SP2 at least surrounding the partial area of the light-transmitting hole HO. A sidewall of the second separation pillar SP2 may be provided with a cut-off groove SLG at least surrounding the partial area of the light-transmitting hole HO. For example, the second separation pillar SP2 may be disposed in the same layer as the first source-drain layer SD1. The second separation pillar SP2 may include a first separation layer SP21 disposed in the same layer as the first sub-layer SD11, a second separation layer SP22 disposed in the same layer as the second sub-layer SD12 and a third separation layer SP23 disposed in the same layer as the third sub-layer SD13. A boundary of the second separation layer SP22 is retracted inside boundaries of the first separation layer SP21 and the third separation layer SP23, forming the cut-off groove SLG.

The light-emitting layer EL covers the second separation pillar SP2 and is disconnected at the cut-off groove SLG, thereby cutting off, through the second separation pillar SP2, the path for water vapor to erode the light-emitting device LD. A structure of the second separation pillar SP2 may be the same as the structure of the first separation pillar SP1 and the second separation pillar SP2 may be disposed in the same layer as the first separation pillar SP1, which will not be described in detail here.

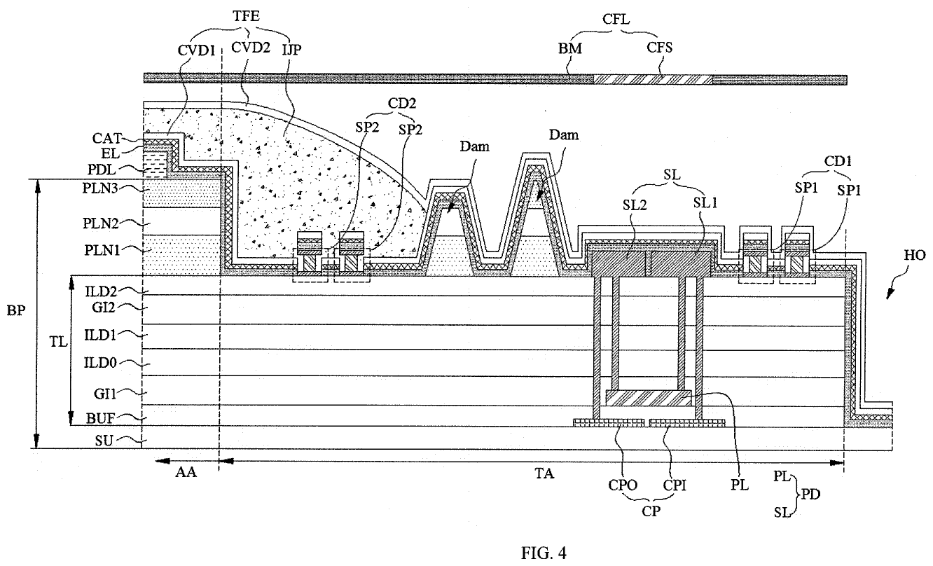

As shown in FIGS. 3 and 4, the encapsulation layer TFE is used to protect the light-emitting device LD, which may adopt the thin film encapsulation. The encapsulation layer TFE may include a first inorganic layer CVD1, an organic layer IJP and a second inorganic layer CVD2.

In some embodiments, the first inorganic layer may cover each light-emitting device LD, that is, the first inorganic layer may cover a surface of the second electrode CAT away from the substrate SU. Furthermore, the first inorganic layer extends from the display area AA into the transition area TA, covers the barrier dam Dam, and may further cover the first separation component CD1 and the second separation component CD2. The first inorganic layer CVD1 may be disconnected at the cut-off groove SLG, or may be continuous. A material of the first inorganic layer CVD1 may include the inorganic insulation material such as silicon nitride or silicon oxide.

The organic layer IJP may be disposed on a surface of the first inorganic layer CVD1 away from the substrate SU, and a boundary of the organic layer IJP may be limited to inside a boundary of the first inorganic layer CVD1 by a peripheral barrier dam located in the peripheral area WA. A material of the organic layer IJP may be the organic material such as resin. A structure of the peripheral barrier dam may be the same as the barrier dam Dam in any embodiment of the present disclosure, or other structures may also be adopted. Moreover, the organic layer IJP may be limited by the barrier dam Dam to a side of the barrier dam Dam away from the light-transmitting hole HO.

The second inorganic layer CVD2 may cover the organic layer IJP and the first inorganic layer CVD1 that is not covered by the organic layer IJP. The intrusion of water and oxygen may be blocked by the second inorganic layer CVD2, and the planarization is achieved through the organic layer IJP with flow (during the manufacturing process). The second inorganic layer CVD2 extends from the display area AA into the transition area TA, and is stacked on a surface, away from the substrate SU, of the first inorganic layer CVD1 covering the barrier dam Dam, the first separation component CD1 and the second separation component CD2. The second inorganic layer CVD2 may be disconnected at the cut-off groove SLG, or may be continuous. A material of the second inorganic layer CVD2 may include the inorganic insulation material such as silicon nitride or silicon oxide.

Further, as shown in FIG. 3, the display panel of the present disclosure may further include a color filter layer CFL disposed on a side of the encapsulation layer TFE away from the substrate SU. The color filter layer CFL may include filter parts CF distributed in an array. The filter part CF may only transmit monochromatic light, and respective filter parts CF may overlap with the light-emitting devices LD in a one-to-one correspondence, so that the light emitted by at least one light-emitting device LD may pass through the filter part CF overlapped with the light-emitting device LD. Two adjacent filter parts CF may be separated by a light-absorbing structure BM. The light-absorbing structure BM may be made of a black material, or may be formed by stacking two adjacent filter parts CF.

In an embodiment in which different light-emitting devices LD may emit monochromatic light of different colors, the light-emitting device LD emits light in the same color as the color of the filter part CF overlapped with the light-emitting device LD. The filter part CF may absorb external light of other colors, thereby reducing the external light irradiating to the first electrode ANO and the second electrode CAT. Accordingly, the reflection of ambient light by the first electrode ANO and the second electrode CAT is weakened, which is beneficial to improving the display effect, especially the display effect in a dark condition.

In an embodiment in which individual light-emitting devices LD emit light with the same color, the color display may be achieved through the color filter layer CFL. In addition, the color filter layer CFL may also play a role in reducing reflection.

In addition, the display panel may further include other film layers such as a touch layer and a transparent cover plate disposed on the side of the encapsulation layer TFE away from the substrate SU, which will not be described in detail here. The color filter layer CFL may be located on a side of the touch layer away from the driving backplane BP, and the transparent cover plate may be located on a side of the color filter layer CFL away from the driving backplane BP.

As shown in FIGS. 2 and 4, the photoelectric sensing device PD may be used to detect light intensity, which may be disposed on the driving backplane BP and located in the transition area TA and between the barrier dam Dam and the first separation component CD. The photoelectric sensing device PD is integrated in the display panel by using the space of the transition area TA, without the need to increase the space specifically to arrange the photoelectric sensing device PD, which can achieve the detection of the ambient light. Furthermore, due to the blocking of the barrier dam Dam, it is difficult for the organic layer IJP to block the photoelectric sensing device PD, which is beneficial to reducing interference.

Alternatively, the photoelectric sensing device PD may also be disposed between the second separation component CD2 and the barrier dam Dam.

In some embodiments of the present disclosure, the number of photoelectric sensing devices PD is more than one, for example, two, three, four, five or more. Individual photoelectric sensing devices PD may be distributed around the light-transmitting hole HO. For example, the individual photoelectric sensing devices PD each have an arc-shaped structure and distributed at intervals around the light-transmitting hole HO along an annular trajectory.

As shown in FIG. 4, the color filter layer CFL may further include a plurality of sensing filter parts CFS of different colors. One sensing filter part CFS may be overlapped with one photoelectric sensing device PD, and the sensing filter part CFS may transmit the monochromatic light, so that the photoelectric sensing device PD overlapped with the sensing filter part CFS can only detect the intensity of the monochromatic light in the ambient light. The light intensities of monochromatic light of a plurality of colors can be detected, respectively, through a plurality of sensing filter parts CFS of different colors and a plurality of photoelectric sensing devices PD overlapped with these sensing filter parts CFS, so as to adjust the color of the display picture or the shooting picture.

Furthermore, a shape of the sensing filter part CFS may be the same as a shape of the photoelectric sensing device PD overlapped with this sensing filter part CFS, and both of them may be arc-shaped. Individual sensing filter parts CFS may be distributed at intervals around the light-transmitting hole HO along the annular trajectory. A boundary of the sensing filter part CFS may be aligned with a boundary of the photoelectric sensing device PD overlapped with the sensing filter part CFS.

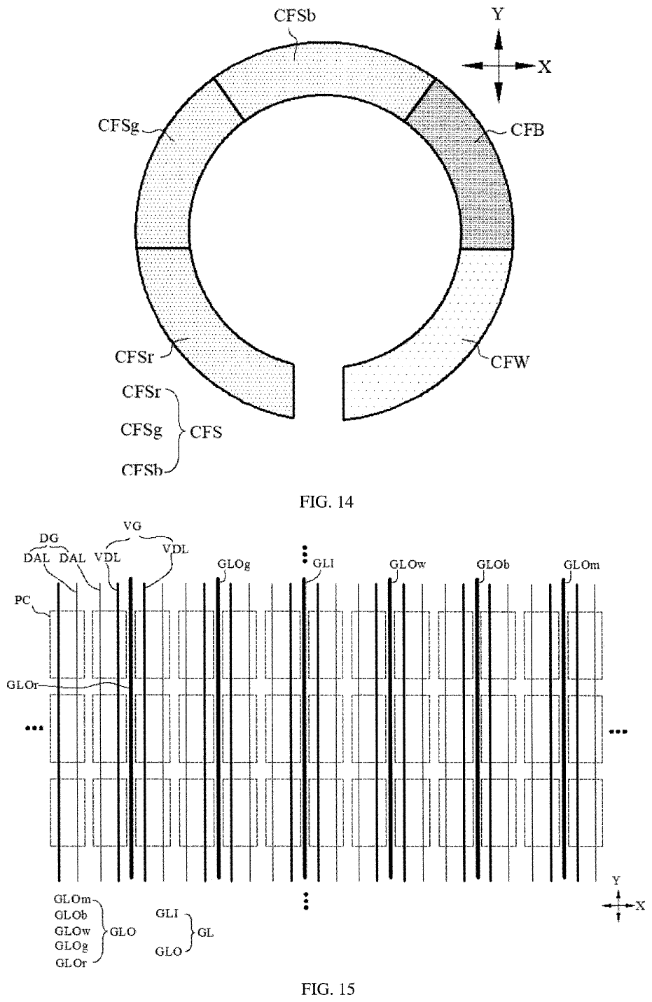

Furthermore, as shown in FIG. 14, in some embodiments of the present disclosure, the color filter layer CFL may further include a transparent part CFW that can transmit white light. One transparent part CFW is overlapped with one photoelectric sensing device PD, and the total light intensity of the ambient light may be detected through the transparent part CFW and the photoelectric sensing device PD overlapped with the transparent part CFW. In addition, a shape of the transparent part CFW is the same as a shape of the photoelectric sensing device PD overlapped with the transparent part CFW, and both of them may be arc-shaped. The transparent part CFW and the sensing filter part CFS may be distributed at intervals around the light-transmitting hole HO. A boundary of the transparent part CFW may be aligned with a boundary of the photoelectric sensing device PD overlapped with the transparent part CFW.

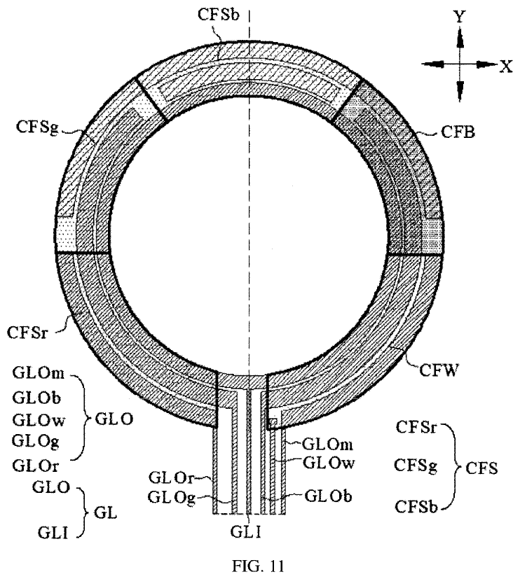

Further, as shown in FIGS. 11 and 14, in some embodiments of the present disclosure, the color filter layer CFL may further include a light-absorbing part CFB. One light-absorbing part CFB is overlapped with one photoelectric sensing device PD, and the light-absorbing part CFB may be made of black resin or another light-absorbing material, which can prevent the ambient light from irradiating to the photoelectric sensing device PD overlapped with the light-absorbing part CFB. Due to the shielding of the light-absorbing part CFB, it is difficult for the photoelectric sensing device PD overlapped with the light-absorbing part CFB to receive the ambient light, and a signal output by this photoelectric sensing device PD may be used as a reference value for other photoelectric sensing devices PD to determine the light intensity. For example, the signal detected and output by the photoelectric sensing device PD overlapped with the light-absorbing part CFB is regarded as a signal corresponding to the zero light intensity. Furthermore, a shape of the light-absorbing part CFB may be the same as a shape of the photoelectric sensing device PD overlapped with the light-absorbing part CFB, and both of them may be arc-shaped. The light-absorbing part CFB, the transparent part CFW and the sensing filter part CFS are distributed at intervals around the light-transmitting hole HO, thereby forming an annular structure. A boundary of the light-absorbing part CFB may be aligned with a boundary of the photoelectric sensing device PD overlapped with the light-absorbing part CFB. The light-absorbing part CFB, the transparent part CFW and the sensing filter part CFS may be separated by the light-absorbing structure BM.

In some embodiments of the present disclosure, the display panel may not be provided with the filter part CF, that is, the color filter layer CFL may not include the filter part CF and the light-absorbing structure BM located in the display area AA. Only the light-absorbing part CFB, the transparent part CFW and the sensing filter part CFS are disposed at positions corresponding to the positions of the light-transmitting holes HO. In addition, the light-absorbing part CFB, the transparent part CFW and the sensing filter part CFS are disposed in the same layer and on the color filter layer CFL, but are located on different layers from the filter part CF and the light-absorbing structure BM.

As shown in FIG. 3, the photoelectric sensing device PD includes a photoelectric sensing layer PL and a sensing electrode SL.

In some embodiments, as shown in FIGS. 7 and 10, photoelectric sensing layers PL of individual photoelectric sensing devices PD may be distributed at intervals around the light-transmitting hole HO to form an annular structure. Alternatively, a polygonal structure may also be formed.

As shown in FIGS. 7 to 9, the sensing electrode SL may include a first electrode part SL1 and a second electrode part SL2. The photoelectric sensing layer PL may perform photoelectric conversion under illumination, which is input by one of the first electrode part SL1 and the second electrode part SL2 and output by the other one, and the light intensity may be determined according to the output electrical signal. A shape of an orthographic projection of the photoelectric sensing layer PL on the substrate SU may be regarded as a shape of the photoelectric sensing device PD.

For example, the sensing electrode SL may be disposed on a side of the photoelectric sensing layer PL away from the substrate SU, that is, the first electrode part SL1 and the second electrode part SL2 may be located on the same side of the photoelectric sensing layer PL. Both the first electrode part SL1 and the second electrode part SL2 are overlapped with and coupled to the photoelectric sensing layer PL, so as to input and output the signal.

Furthermore, as shown in FIGS. 3 and 4, photoelectric sensing layers PL of at least part of the photoelectric sensing devices PD may be disposed in the same layer as the first semiconductor layer POL or the second semiconductor layer IGL. Alternatively, in order to simplify the process, the photoelectric sensing layer PL of each photoelectric sensing device PD may be disposed in the same layer as the first semiconductor layer POL or the second semiconductor layer IGL. The sensing electrode SL may be disposed in the same layer as one of the first source-drain layer SD1, the second source-drain layer SD2 and the third source-drain layer SD3. For example, the sensing electrode SL may be disposed in the same layer as the first separation component CD1 and the second separation component CD2, which may be located in the first source-drain layer SD1.

Alternatively, the first electrode part SL1 and the second electrode part SL2 may also be located on both sides of the photoelectric sensing layer PL.

The following takes a sensing electrode SL of one photoelectric sensing device PD as an example to illustrate patterns of the first electrode part SL1 and the second electrode part SL2.

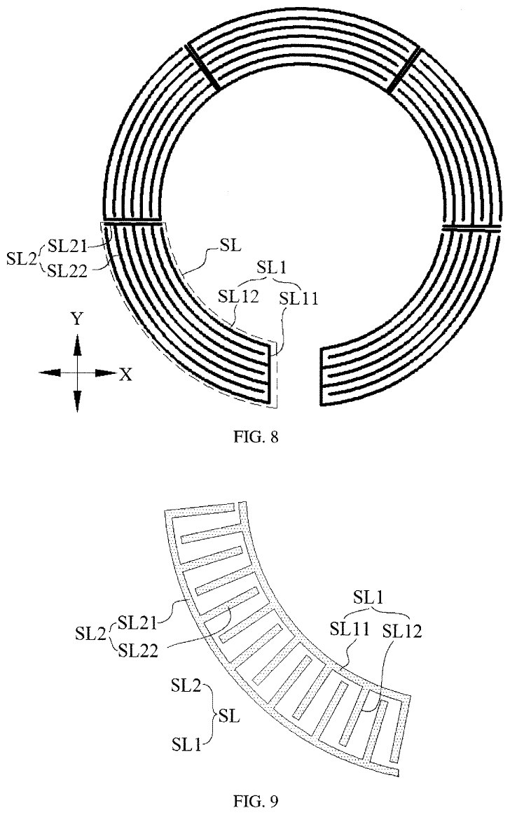

As shown in FIGS. 7 and 8, in some embodiments of the present disclosure, the first electrode part SL1 and the second electrode part SL2 may be located on a side of the photoelectric sensing layer PL away from the substrate SU.

The first electrode part SL1 may include a first electrode body SL11 and a plurality of first interdigital parts SL12. The first interdigital part SL12 is an arc-shaped structure surrounding the light-transmitting hole HO, and individual first interdigital parts SL 12 may be distributed at intervals along the direction away from the light-transmitting hole HO. The first electrode body SL11 may extend along the radial direction of the light-transmitting hole HO and may be coupled to each first interdigital part SL12.

The second electrode part SL2 may include a second electrode body SL21 and a plurality of second interdigital parts SL22. The second interdigital part SL22 is an arc-shaped structure surrounding the light-transmitting hole HO, and individual second interdigital parts SL22 may be distributed at intervals along the direction away from the light-transmitting hole HO. The second electrode body SL21 is coupled to each second interdigital part SL22.

In the same sensing electrode SL, the first interdigital parts SL12 and the second interdigital parts SL22 may be alternately distributed along the radial direction of the light-transmitting hole HO. That is to say, the first electrode part SL1 and the second electrode part SL2 may be two comb-shaped structures inserted into each other, which can improve the light transmittance and increase an overlapping area with the photoelectric sensing layer PL, so as to play a role of reducing the resistance and facilitating the reception of a transmission signal.

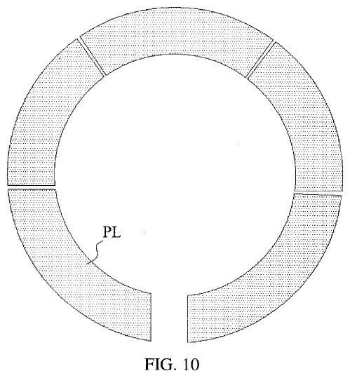

As shown in FIG. 9, in some embodiments of the present disclosure, the first electrode part SL1 may include a first electrode body SL11 and a plurality of first interdigital parts SL12. The first electrode body SL11 may be an arc-shaped structure surrounding the light-transmitting hole HO, and individual first interdigital parts SL12 are coupled to a side of the first electrode body SL11 away from the light-transmitting hole HO and distributed at intervals along an extension direction of the first electrode body SL11.

The second electrode part SL2 may include a second electrode body SL21 and a plurality of second interdigital parts SL22. The second electrode body is an arc-shaped structure surrounding the light-transmitting hole HO and is located on a side of the first electrode body SL11 away from the light-transmitting hole HO. Individual second interdigital parts SL22 are coupled to a side of the second electrode body SL21 close to the light-transmitting hole HO, and distributed at intervals along an extension direction of the second electrode body SL21.

In the same sensing electrode SL, the first interdigital parts SL12 and the second interdigital parts SL22 may be alternately distributed along a direction surrounding the light-transmitting hole HO. That is to say, the first electrode part SL1 and the second electrode part SL2 may be two comb-shaped structures inserted into each other.

In other embodiments of the present disclosure, the sensing electrode SL may also adopt other structures, as long as the input and output of the signal can be realized. In addition, the first electrode part SL1 and the second electrode part SL2 may also be specially provided conductive film layers, and are not necessarily disposed in the same layer as the first source-drain layer SD1 or the second source-drain layer SD2.

As shown in FIGS. 11 to 13 and 15, in order to facilitate the signal transmission of the photoelectric sensing device PD, a plurality of leads GL for signal transmission may be provided for the photoelectric sensing device PD. Each photoelectric sensing device PD may be coupled to at least one lead GL for signal input, and coupled to at least one lead GL for signal output. For example, the first electrode part SL1 is coupled to a lead GL for signal input, and the second electrode part SL2 is coupled to a lead GL for signal output. These leads GL may be extended into the peripheral area WA and may be coupled with a chip or a circuit in the peripheral area WA to facilitate to input and output signals.

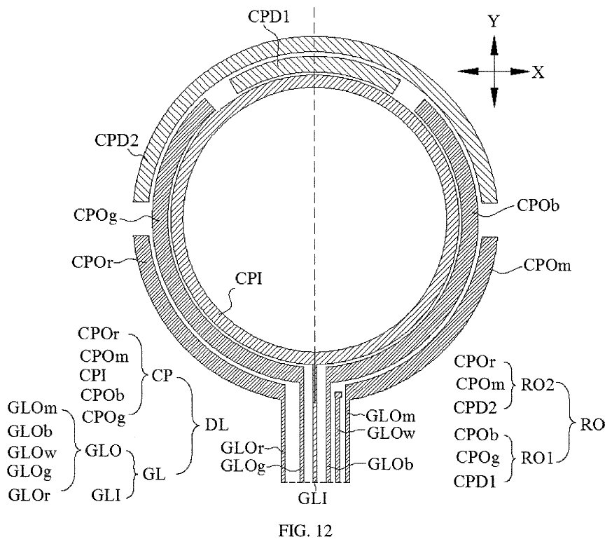

In some embodiments of the present disclosure, as shown in FIGS. 3 and 12, the display panel further includes a lead layer DL, which may be disposed on the driving backplane BP. The lead layer DL may be disposed in the same layer as the light-shielding layer BSM and may be insulated from the light-shielding layer BSM to expand the wiring space to facilitate the wiring, without shielding the photoelectric sensing device PD. In addition, the light-shielding layer BSM and the lead layer DL may be made of a material such as a reflective metal, and is located between the photoelectric sensing device PD and the substrate SU. The reflection of the lead layer DL can illuminate to the photoelectric sensing device PD, reducing light loss and improving detection precision.

Alternatively, the lead layer DL may also be disposed in the same layer as other conductive film layers, as long as signal transmission can be achieved.

As shown in FIG. 12, the lead layer DL may include a connection part CP and a plurality of leads GL, where:

As shown in FIGS. 1 and 12, the lead GL extends to the peripheral area WA. The connection part CP surrounds outside the light-transmitting hole HO and is overlapped with the sensing electrode SL. The first electrode part SL1 of the sensing electrode SL is coupled to the lead GL through the connection part CP, and second electrode parts SL2 of at least part of the sensing electrodes SL are coupled to the leads GL through the connection parts CP. Second electrode portions SL2 of a part of the sensing electrodes SL may be directly coupled to the leads GL, without through the connection parts CP. The leads GL coupled to the first electrode part SL1 and the second electrode part SL2 are different, and the leads GL coupled to different second electrode parts SL2 are also different.

A detailed illustrative description of structures of the connection part CP and the lead GL is given below.

As shown in FIGS. 11 and 12, the connection part CP may be used to transmit input and output signals for the photoelectric sensing device PD. Therefore, the connection part CP may include an input part CPI and a plurality of output parts CPO surrounding the input part CPI. The input part CPI and the output part CPO are coupled to different leads GL, and different output parts CPO may be coupled to different leads GL.

At least part of the first electrode parts SL1 may be coupled to the leads GL through the input part CPI, and at least part of the second electrode parts SL2 may be coupled to the leads GL through the output part CPO.

For convenience of description, the lead GL coupled to the input part CPI may be defined as an input lead GLI. Furthermore, the lead GL coupled to the output part CPO and the lead GL directly coupled to the second electrode part SL2 are both defined as the output lead GLO.

As shown in FIGS. 11 and 12, in some embodiments of the present disclosure, the input part CPI may be a continuous annular structure surrounding the light-transmitting hole HO, and the input part CPI is both overlapped with and coupled to the first electrode part of each sensing electrode SL. The input part CPI may be coupled with the input lead GLI, so that signals can be input to respective photoelectric sensing devices PD simultaneously through the input leads GIL and one input part CPI.

Each output part CPO is an arc-shaped structure surrounding outside the input part CPI, and individual output parts CPO may be disposed to surround the input part CPI along at least two annular trajectories, thereby obtaining at least two output rings RO, that is, the connection part CP may include at least two output rings RO surrounding outside the input part CPI. One output ring RO may include at least one output part CPO, and two adjacent output rings RO may be distributed at intervals along the radial direction of the light-transmitting hole HO.

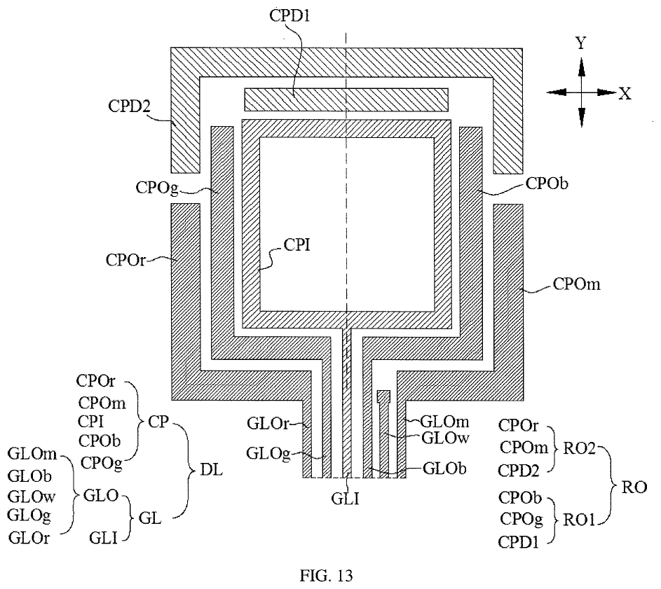

In addition, as shown in FIG. 13, the input part CPI may be a continuous polygonal structure surrounding the light-transmitting hole HO, or an annular structure, as long as it can surround outside the light-transmitting hole HO. Correspondingly, individual output parts CPO may be distributed along a polygonal trajectory. The polygon may be a rectangle, pentagon, hexagon, etc.

Further, as shown in FIGS. 11 and 12, individual output parts CPO may be symmetrically distributed along a central axis of the light-transmitting hole HO in the column direction Y.

In some embodiments of the present disclosure, the number of output rings RO is two, such as an output ring RO1 and an output ring RO2 shown in FIGS. 12 and 13. The two output rings RO have the same number of output parts CPO.

A width of the input part CPI in the radial direction of the light-transmitting hole HO is smaller than a width of the photoelectric sensing device PD in the radial direction. A width of the output part CPO in the radial direction of the light-transmitting hole HO is smaller than the width of the photoelectric sensing device PD in the radial direction. Both the input part CPI and the output part CPO may be overlapped with the sensing electrode SL to facilitate the connection.

Further, both the photoelectric sensing device PD and the input part CPI have the annular structure. An inner boundary (a boundary close to the light-transmitting hole HO) of an orthographic projection of the input part CPI on the substrate SU is located inside an inner boundary (a boundary close to the light-transmitting hole HO) of an orthographic projection of the photoelectric sensing device PD on the substrate SU, to prevent the input part CPI from being damaged when the light-transmitting hole HO is opened through thermal cutting or other processes. In addition, an outer boundary (a boundary away from the light-transmitting hole HO) of an orthographic projection of an output part CPO of an output ring RO farthest from the light-transmitting hole HO on the substrate SU may be located within an orthographic projection of the second separation component CD2 on the substrate SU, or may be located between the second separation component CD2 and the barrier dam Dam, which is beneficial to increasing the width of the output part CPO and reducing the resistance. Alternatively, it may also be located within an outer boundary (a boundary away from the light-transmitting hole HO) of the orthographic projection of the photoelectric sensing device PD on the substrate SU.

Further, as shown in FIGS. 12 and 13, in order to improve the uniformity of the film layer, the connection part CP further includes a dummy part CPD. The dummy part CPD is an arc-shaped structure surrounding outside the input part CPI and is floating or in a floating connection state, that is, the dummy part CPD does not receive any electrical signal. At least one output ring RO further includes at least one dummy part CPD, and the dummy part CPD and the output part CPO of the same output ring RO may be distributed at intervals along the annular trajectory. As shown in FIGS. 12 and 13, the output ring RO1 includes a dummy part CPD1, and the output ring RO2 includes a dummy part CPD2.

In order to facilitate the connection between the first electrode part SL1 and the input part CPI, and the connection between the second electrode part SL2 and the output part CPO, first electrode parts SL1 and second electrode parts SL2 of at least a part of the sensing electrodes SL may be provided with a connection pad extending outward, and the connection pad may be coupled to the input part CPI and the output part CPO through one or more via holes.

As shown in FIGS. 12 and 13, the input lead GL1 and the output lead GL2 are described in detail below.

Individual output parts CPO are distributed around the input part CPI, forming a plurality of output rings RO. Each output ring RO has a gap formed by two adjacent output parts CPO spaced apart from each other, and each output ring RO has a gap distributed along the column direction Y, and forms a channel penetrating along the central axis in the column direction Y of the light-transmitting hole HO. Widths of these gaps in different output rings RO may be different. Based on this, the input lead GLI may pass through the channel along the column direction Y and extend to the peripheral area WA, that is, the input lead GLI may extend along the central axis in the column direction Y of the light-transmitting hole HO. Moreover, each output part CPO may be coupled to one output lead GLO, and at least one output lead GIO is coupled to the output part CPO. Individual output leads GLO may be distributed at intervals on both sides of the input lead GLI, but the number of output leads GLO on both sides can be the same or different. Each output lead GLO also extends along the column direction Y to the peripheral area WA.

In some embodiments of the present disclosure, as shown in FIG. 15, at least one lead GL is located between two power lines VDL of one power line group VG, that is, the data line DAL and the lead GL may be separated by the power line VDL, thereby playing a shielding role through a constant first power signal VDD to prevent the data signal DA and the signal of the photoelectric sensing device PD from interfering with each other.

Further, as shown in FIG. 16, the light-shielding line BL extending along the row direction X may have a gap Gap, that is, the light-shielding line BL is disconnected at the gap Gap. The lead GL may pass through the gap Gap and is spaced apart from the light-shielding line BL, thereby avoiding a short circuit between the light-shielding line BL and the lead GL located on the same layer.

As shown in FIGS. 11-14, in some embodiments of the present disclosure, the number of photoelectric sensing devices PD is five, and they are distributed in an annular shape around the light-transmitting hole HO. The lengths of the photoelectric sensing devices PD on the distribution trajectory may be the same. The number of sensing filter parts CFS is three, and colors of the three sensing filter parts CFS are different from each other. For example, the colors of the three sensing filter parts CFS are red, green and blue, respectively. Both the number of transparent parts CFW and the number of light-absorbing parts CFB are one, and the intensity of the three colors of red, green, and blue light in the ambient light can be detected through photoelectric sensing devices PD overlapped with the three sensing filter parts CFS. The intensity of red, green, and blue light in the ambient light may be detected by the photoelectric sensing devices PD overlapped with the three sensing filter parts CFS. The intensity of the ambient light is detected by the photoelectric sensing device PD overlapped with the transparent part CFW. The photoelectric sensing device PD overlapped with the light-absorbing part CFB provides a signal without illumination as a reference. As shown in FIG. 14, a red sensing filter part CFS is a sensing filter part CFSr, a green sensing filter part CFS is a sensing filter part CFSg, and a blue sensing filter part CFS is a sensing filter part CFSb.

The number of input leads GLI is one, which may extend along the column direction Y, and is coupled to the input part CPI. The input part CPI may be coupled to first electrode parts SL1 of respective photoelectric sensing devices PD through a plurality of via holes. Furthermore, the number of output leads GLO may be five, each of the four output leads GLO may be coupled to one output part CPO, and one output part CPO may be coupled to the second electrode part SL2 of one photoelectric sensing device PD through the via hole.

For example, as shown in FIGS. 11 to 14, an output lead GLOw coupled to the photoelectric sensing device PD overlapped with the transparent part CFW is directly coupled to the second electrode part SL2 of the photoelectric sensing device PD without being coupled to the second electrode part SL2 through the output portion CPO, so as to save space.

An output part CPOr coupled to the output lead GLOr is overlapped with the sensing filter part CFSr. An output part CPOg coupled to the output lead GLOg is overlapped with the sensing filter part CFSg. An output part CPOb coupled to the output lead GLOb is overlapped with the sensing filter part CFSb. An output part CPOm coupled to the output lead GLOm is overlapped with the light-absorbing part CFB.

In some embodiments of the present disclosure, as shown in FIG. 17, six sensing filter parts CFS, two transparent parts CFW and two light-absorbing parts CFB may be provided around the light-transmitting hole HO. Alternatively, more sensing filter parts CFS, transparent parts CFW and light-absorbing parts CFB may also be provided. Alternatively, there may be less sensing filter parts CFS, transparent parts CFW and light-absorbing parts CFB. In other embodiments of the present disclosure, the light-absorbing part CFB may not be provided. Correspondingly, the number of photoelectric sensing devices PD is equal to the total number of sensing filter parts CFS, transparent parts CFW and light-absorbing parts CFB.

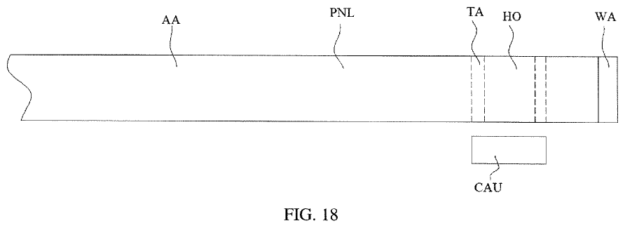

Embodiments of the present disclosure further provide a terminal device. The terminal device may be a mobile phone, a tablet computer, a television, or other electronic devices with camera functions, which will not be listed here one by one. As shown in FIG. 18, the terminal device of the present disclosure may include a display panel PNL and a photosensitive element CAU.

In some embodiments, the display panel PNL may be the display panel PNL in any of the above embodiments. For its structure, reference may be made to the above embodiments of the display panel PNL, which will not be described in detail here.

The photosensitive element CAU may be disposed on the side of the driving backplane BP away from the light-emitting device LD. An orthographic projection of the photosensitive element CAU on the driving backplane BP is at least partially overlapped with the orthographic projection of the light-transmitting hole HO on the driving backplane BP, that is, the photosensitive element CAU is overlapped with the light-transmitting hole HO.

In some embodiments of the present disclosure, the number of light-transmitting holes HO is more than one. The number of photosensitive elements CAU is the same as the number of light-transmitting holes HO, and respective photosensitive elements CAU are overlapped with respective light-transmitting holes HO in a one-to-one correspondence. The external light may irradiate onto the corresponding photosensitive element CAU by transmitting the light-transmitting hole HO. The photosensitive element CAU may generate an electrical signal according to the light transmitted through the corresponding light-transmitting hole HO to generate an image. The photosensitive element CAU may include an image sensor, such as a CCD image sensor or a CMOS image sensor.

The photosensitive element CAU may generate an image based on visible light, or may also generate an image based on infrared rays or other light. For example, the photosensitive element CAU may include an infrared sensor, which forms an infrared image by receiving infrared rays from the outside, so as to identify fingerprint patterns, iris patterns, facial patterns, etc. according to the infrared image. In addition, the photosensitive element CAU may also use a Light Detection and Ranging (LIDAR) sensor.

The photosensitive element CAU may be used not only in cameras that capture images, but also in small lamps that measure distances by outputting and detecting light, and output light.

Other embodiments of the present disclosure will be readily apparent to those skilled in the art from consideration of the specification and practice of the application disclosed herein. This application is intended to cover any modification, use or adaptation of the present disclosure, and these modifications, uses or adaptations follow the general principles of the present disclosure and include common knowledge or conventional technical means in the technical field not disclosed in the present disclosure. The specification and embodiments are to be considered exemplary only, with the actual scope and spirit of the disclosure being indicated by the appended claims.

1. A display panel with a light-transmitting hole, a display area located outside the light-transmitting hole, a peripheral area located outside the display area and a transition area located between the light-transmitting hole and the display area, comprising:
a driving backplane;
a barrier dam, disposed on the driving backplane, located in the transition area, and at least surrounding a partial area of the light-transmitting hole;
a first separation component, disposed on the driving backplane and located in the transition area, wherein the first separation component and the barrier dam are distributed at intervals in a radial direction of the light-transmitting hole, the first separation component comprises a first separation pillar at least surrounding the partial area of the light-transmitting hole, and a sidewall of the first separation pillar is provided with a cut-off groove at least surrounding the partial area of the light-transmitting hole;
a light-emitting devices, disposed on a side of the driving backplane and located in the display area;
a photoelectric sensing device, disposed between the barrier dam and the first separation component; and
an encapsulation layer, covering the light-emitting device, the barrier dam and the first separation component, wherein the encapsulation layer comprises an organic layer defined on a side of the barrier dam away from the light-transmitting hole.

2. The display panel according to claim 1, wherein a number of photoelectric sensing devices is more than one; and
the display panel comprises:
a color filter layer, disposed on the side of the driving backplane where the light-emitting device is disposed, and comprising a plurality of sensing filter parts with different colors, wherein one sensing filter part is overlapped with one photoelectric sensing device.

3. The display panel according to claim 2, wherein the color filter layer further comprises a transparent part configured to transmit white light, one transparent part is overlapped with one photoelectric sensing device, and the transparent part and the sensing filter parts are distributed around the light-transmitting hole.

4. The display panel according to claim 3, wherein the color filter layer further comprises a light-absorbing part, one light-absorbing part is overlapped with one photoelectric sensing device, and the light-absorbing part, the transparent part and the sensing filter parts are distributed around the light-transmitting hole.

5. The display panel according to claim 4, wherein the photoelectric sensing devices each has an arc-shaped structure and are distributed at intervals around the light-transmitting hole along an annular trajectory.

6. The display panel according to claim 5, wherein the photoelectric sensing device comprises:
a photoelectric sensing layer; and
a sensing electrode, disposed on a side of the photoelectric sensing layer and comprising a first electrode part and a second electrode part disposed at intervals, wherein the first electrode part and the second electrode part are overlapped with and coupled to the photoelectric sensing layer.

7. The display panel according to claim 6, wherein:
the first electrode part comprises a first electrode body and a plurality of first interdigital parts with an arc-shaped structure surrounding the light-transmitting hole and distributed at intervals in a direction away from the light-transmitting hole, wherein the first electrode body is coupled to each first interdigital part;
the second electrode part comprises a second electrode body and a plurality of second interdigital parts with an arc-shaped structure surrounding the light-transmitting hole and distributed at intervals in the direction away from the light-transmitting hole, wherein the second electrode body is coupled to each second interdigital part; and
the first interdigital parts and the second interdigital parts are, in a same sensing electrode, alternately distributed in the radial direction of the light-transmitting hole.

8. The display panel according to claim 6, wherein:
the first electrode part comprises a first electrode body with an arc-shaped structure surrounding the light-transmitting hole and a plurality of first interdigital parts coupled to a side of the first electrode body away from the light-transmitting hole and distributed at intervals in an extension direction of the first electrode body;
the second electrode part comprises a second electrode body with an arc-shaped structure surrounding the light-transmitting hole and located on the side of the first electrode body away from the light-transmitting hole and a plurality of second interdigital parts coupled to a side of the second electrode body close to the light-transmitting hole and distributed at intervals in an extension direction of the second electrode body; and
the first interdigital parts and the second interdigital parts are, in a same sensing electrode, alternately distributed in a circumferential direction of the light-transmitting hole.

9. The display panel according to claim 7, wherein the driving backplane comprises:
a lead layer, disposed on a side of the photoelectric sensing layer away from the sensing electrode, and comprising a connection part surrounding outside the light-transmitting hole and a lead extending to the peripheral area, wherein a first electrode part of each sensing electrode and second electrode parts of at least part of sensing electrodes are coupled to the lead via the connection part; and
a lead coupled to the first electrode part and a lead coupled to the second electrode part are different, and leads coupled to different second electrode parts are different.

10. The display panel according to claim 9, wherein the connection part comprises an input part and a plurality of output parts surrounding outside the input part, the input part and the output parts are coupled to different leads, and different output parts are coupled to different leads; and
at least part of first electrode parts are coupled to the lead via the input part, and at least part of second electrode parts are coupled to the lead via the output parts.

11. The display panel according to claim 10, wherein the input part is a continuous annular structure or a polygonal structure surrounding the light-transmitting hole, the input part is both overlapped with and coupled to the first electrode part of each sensing electrode, and each output part is an arc-shaped structure surrounding outside the input part; and
individual leads are distributed at intervals in a row direction and are extended to the peripheral area in a column direction.

12. The display panel according to claim 11, wherein the connection part comprises at least two output rings surrounding outside the input part, one output ring comprises at least one output part, and two adjacent output rings are distributed at intervals in the radial direction of the light-transmitting hole.

13. The display panel according to claim 12, wherein the connection part further comprises:
a dummy part with an arc-shaped structure surrounding outside the input part, wherein the dummy part is floating; and
wherein at least one output ring further comprises at least one dummy part, and a dummy part and an output part of a same output ring are distributed at intervals along an annular trajectory.

14. The display panel according to claim 12, wherein the output parts are symmetrically distributed along a central axis in the column direction of the light-transmitting hole, and at least one lead is directly coupled to one second electrode part.

15. The display panel according to claim 12, wherein a lead coupled to the input part is defined as an input lead, and a lead coupled to the output part and a lead directly coupled to the second electrode part are defined as output leads; and
the input lead is extended along a central axis in the column direction of the light-transmitting hole, and individual output leads are distributed at intervals on both sides of the input lead.

16. The display panel according to claim 15, wherein the number of photoelectric sensing devices is five, a number of sensing filter parts is three and colors of the sensing filter parts are different from each other, a number of transparent parts and a number of light-absorbing parts are one, a number of input leads is one, and a number of output leads is five; and
wherein a number of output rings is two, and the two output rings have a same number of output parts; and
an output lead coupled to the photoelectric sensing device overlapped with the transparent part is directly coupled to a second electrode part of the photoelectric sensing device.

17. (canceled)

18. The display panel according to claim 15, wherein the driving backplane comprises a plurality of pixel circuits distributed in an array on the display area and comprising a plurality of transistors, and a plurality of data line groups and power line groups alternately distributed along the row direction, and wherein two adjacent columns of pixel circuits are arranged symmetrically; and
the data line groups and the power line groups are alternately distributed at intervals along the row direction, one data line group comprises two data lines, one power line group comprises two power lines, and one column of pixel circuits is coupled to one data line and one power line.

19. The display panel according to claim 18, wherein the driving backplane comprises:
a substrate;
a light-shielding layer, disposed on a side of the substrate, wherein the lead layer is disposed in a same layer as the light-shielding layer and is insulated from the light-shielding layer; and
a transistor layer, disposed on a side of the light-shielding layer away from the substrate, and comprising the transistors of the pixel circuits;
wherein the data lines and the power lines are located on a side of the transistor layer away from the substrate, the power lines are coupled to the light-shielding layer, and at least one lead is located between two power lines of one power line group;
wherein the light-shielding layer comprises a plurality of light-shielding units distributed in an array and light-shielding lines coupled to respective light-shielding units along the row direction and the column direction, one light-shielding unit is overlapped with at least one transistor of at least one pixel circuit, and at least one of a light-shielding line and a light-shielding unit is coupled to a power line; and
at least part of light-shielding lines extended along the row direction each has a gap, and the lead passes through the gap and is spaced apart from the light-shielding line; and
wherein the transistor layer comprises a first semiconductor layer, a first gate insulation layer, a first gate layer, a first insulation layer, a second gate layer, a second insulation layer, a second semiconductor layer, a second gate insulation layer, a third gate layer and a third insulation layer sequentially stacked in a direction away from the substrate;
a photoelectric sensing layer of at least one photoelectric sensing device is disposed in a same layer as one of the first semiconductor layer and the second semiconductor layer; and
the driving backplane further comprises a first source-drain layer, a second source-drain layer and a third source-drain layer disposed sequentially in the direction away from the substrate, the data lines and the power lines are located in the third source-drain layer, and the sensing electrode is disposed in the same layer as one of the first source-drain layer, the second source-drain layer and the third source-drain layer.

20-21. (canceled)

22. The display panel according to claim 1, wherein the first separation component surrounds outside the light-transmitting hole, and the barrier dam surrounds outside the first separation component;
the display panel further comprises:
a second separation component, disposed on the driving backplane and located in the transition area, wherein the second separation component surrounds outside the barrier dam and comprises a second separation pillar at least surrounding the partial area of the light-transmitting hole, and a sidewall of the second separation pillar is provided with a cut-off groove at least surrounding the partial area of the light-transmitting hole; and
the second separation component is covered by the encapsulation layer.

23. A terminal device, comprising:
a display panel with a light-transmitting hole, a display area located outside the light-transmitting hole, a peripheral area located outside the display area and a transition area located between the light-transmitting hole and the display area, comprising:
a driving backplane;
a barrier dam, disposed on the driving backplane, located in the transition area, and at least surrounding a partial area of the light-transmitting hole;
a first separation component, disposed on the driving backplane and located in the transition area, wherein the first separation component and the barrier dam are distributed at intervals in a radial direction of the light-transmitting hole, the first separation component comprises a first separation pillar at least surrounding the partial area of the light-transmitting hole, and a sidewall of the first separation pillar is provided with a cut-off groove at least surrounding the partial area of the light-transmitting hole;
a light-emitting device, disposed on a side of the driving backplane and located in the display area;
a photoelectric sensing device, disposed between the barrier dam and the first separation component; and
an encapsulation layer, covering the light-emitting device, the barrier dam and the first separation component, wherein the encapsulation layer comprises an organic layer defined on a side of the barrier dam away from the light-transmitting hole; and
a photosensitive element, disposed on a side of the driving backplane away from the light-emitting device and overlapped with the light-transmitting hole.
